(19) United States
(12) Patent Application Publication
(10) Pub. No.: US 2003/0013328 A1
(43) Pub. Date: Jan. 16, 2003

(54) Connection assembly for integrated circuit sensors

(76) Inventor: Thomas L. Andrade, Los Gatos, CA (US)

Correspondence Address: DORSEY & WHITNEY LLP, Suite 3400, Four Embarcadero Center, San Francisco, CA, 94111-4187, US

(21) Appl. No.: 10/155,834

(22) Filed: May 22, 2002

Related U.S. Application Data
(60) Provisional application No. 60/292,862, filed on May 22, 2001.

(51) Int. Cl. H05K 1/00

(52) U.S. Cl. 439/76.1

(57) ABSTRACT

An improved connection assembly for an integrated circuit sensor uses direct chip attachment to connect a circuit board directly to the integrated circuit. The circuit board covers and protects the integrated circuit except over the sensor areas. The use of a thin circuit board reduces the physical interference between the circuit board and the sensor area.

### CROSS REFERENCE TO RELATED APPLICATION

This application claims the benefit of priority to U.S. Provisional Patent Application Serial No. 60/292,862 filed on May 22, 2001, which is hereby incorporated by reference.

### FIELD OF THE INVENTION

The present invention relates to an improved method for making the electrical and physical connection between an integrated circuit sensor and an electronic system and to a device using or having that electrical and physical connection.

### BACKGROUND

In an integrated circuit sensor, the sensor elements transduce the external stimulus at or near the element's surface into electrical signals that are acted upon by electrical circuits within the integrated circuit. The sensor elements transduce stimuli such as light, heat, temperature, pressure (static or sound), capacitance (for example as electrical proximity), resistance (for example as electrical surface conductivity), or other stimuli into electrical signals.

A connection assembly is required to connect the integrated circuit to the remainder of the electronic system while not interfering with the transducing properties of the sensor elements. An example of a typical connection assembly for integrated circuit is a plastic package: a plastic encapsulated combination of lead frame, wire bond, and integrated circuit. As well as passing electrical signals between the electronic system and the integrated circuit sensor, the connection assembly may also provide environmental protection to the entire sensor as demonstrated in commercially available sensors.

Because of the intrinsically planar nature of the integrated circuit technology, the sensor area which contains the sensor elements usually exists in roughly the same plane as the connection points, or terminals, of the integrated circuit. A wire bond connection from the integrated circuit to an appropriate wiring substrate extends above the sensor surface and therefore may physically interfere with the proximity required by the sensor elements. A connection assembly that can tolerate the wire bond height is readily available for most optical, pressure, and thermal integrated circuit sensors. In U.S. Pat. No. 4,577,345, Abramov discloses a surface contact sensor used to measure fingerprints in which the package height affects the sensor area. In this disclosure the sensor area is illustrated larger than the finger so that the connection assembly does not interfere with the sensor area.

In U.S. Pat. No. 5,862,248, Salatino et. al. disclose a method to package a fingerprint sensor using a leaded package which has wire bond connections physically distant from the sensor area. A window in the packaging material is provided over the sensor area. Plastic material protects the wire bonds and part of the electrical circuit area from environmental damage. Some examples of environmental damage are mechanical damage due to impact or abrasion, chemical damage due to corrosion, and electrical damage due to static electricity (ESD). In U.S. Pat. No. 6,028,773, Hundt discloses a fingerprint sensor directly mounted to a circuit board. Wire bonds are used to connect the integrated circuit sensor to the circuit board. Hundt also uses plastic material which protects the wire bonds and part of the electrical circuit area from environmental damage.

As the plastic material (or other material) used to protect the wire bonds is not electrically conductive, other methods are used to protect surface sensors from static electrical damage (ESD). These methods usually include the positioning of a conductive material near the sensor area. These methods result in an increased assembly cost.

In U.S. Pat. No. 6,289,114, Mainguet discloses a sweeping-type fingerprint sensor which is reduced in cost versus previous sensors as the sensor area is appreciably smaller than the area of a finger. In this smaller sensor the height of the connection assembly that is in close proximity to the sensor area adversely affects the ability of the finger medium to contact the sensor area. Conversely, the closer the connection assembly is to the sensor area, the more environmental protection is afforded the integrated circuit sensor.

### RELEVANT LITERATURE

U.S. Patent Documents

| U.S. Pat. No. | Date | Inventor | U.S. Class |
|---|---|---|---|
| 4,353,056 | 10/1982 | Tsikos | 340/146.3 E |
| 4,577,345 | March 1986 | Abramov | 382/4 |
| 4,785,338 | November 1988 | Kinoshita et.al | 357/30 |
| 5,051,802 | September 1991 | Prost et.al. | 357/30 |
| 5,207,102 | May 1993 | Takahashi et. al. | 73/727 |
| 5,264,393 | November 1993 | Tamura et.al. | 437/209 |
| 5,382,310 | January 1995 | Ozimek et.al. | 156/275.5 |
| 5,424,249 | June 1995 | Ishibashi et. al. | 437/211 |
| 5,429,006 | July 1995 | Tamori | 73/862.046 |
| 5,485,011 | January 1996 | Lee et.al. | 250/338.1 |
| 5,559,504 | September 1996 | Itsumi et. al. | 340/825.30 |
| 5,622,873 | April 1997 | Kim et. al. | 438/65 |
| 5,748,448 | May 1998 | Hokari | 361/749 |
| 5,822,030 | October 1998 | Uchiyama | 349/149 |
| 5,824,950 | October 1998 | Mosley et. al. | 174/52.4 |
| 5,862,248 | January 1999 | Salatino et. al. | 382/124 |
| 5,901,046 | May 1999 | Ohta et. al. | 361/760 |
| 6,028,773 | February 2000 | Hundt | 361/760 |
| 6,211,936 B1 | April 2001 | Nakamura | 349/152 |
| 6,214,634 B1 | April 2001 | Osajda et. al. | 438/50 |
| 6,289,114 B1 | September 2001 | Mainguet | 382/124 |
| 6,246,566 B1 | June 2001 | Glenn | 361/220 |
| 6,268,231 B1 | July 2001 | Wetzel | 438/48 |

Other Publications

1) FPS110, FPS110B, FPS110E Solid State Fingerprint Sensor datasheet, Veridicom Inc, Document #02-0053-01, Revision F, Oct. 26, 2001.

2) FCD4B14 FingerChip datasheet, ATMEL Inc, Revision 1962C-01/20.

3) FTF 1100 MF1 V2.0 FingerTIP Databook, Infineon Technologies Inc, Revision 3.3 (05.00).

### SUMMARY

The present invention provides a connection assembly to an integrated circuit sensor (and even to integrated circuits other than sensors) that provides environmental protection of the electrical circuit area (non-sensor area) and simultaneously allows a medium, such as a finger, to be sensed (such as when sensing a fingerprint with a contact or swipe sensor) with minimal physical interference. A thin circuit board material, typically less than 100 micrometers, is attached to the integrated circuit sensor using direct circuit board to integrated circuit attachment technologies. These attachment technologies may for example include solder ball and direct compressive attachment technology, or other attachment techniques and structures known in the art. The thin circuit board material is fabricated so as to cover the electrical circuit, but not cover the sensor area.

The circuit board is mechanically attached to the integrated circuit sensor and provides additional strength to the assembly. The circuit board reduces the sensor's need for additional mechanical support. The circuit board contains conductive material which is used to conduct ESD currents discharged near the sensor area. The circuit board material provides optical shielding to the electrical circuits located beneath it. The circuit board material is readily attached to remainder of the electronic system by including exposed connection points for either solder or connector attachment.

### BRIEF DESCRIPTION OF THE DRAWINGS

For a more thorough understanding of the features and advantages of the connection assembly, reference is now made to the detailed description of the invention in which:

FIG. 1 illustrates a representative integrated circuit sensor;

FIG. 2 illustrates and embodiment of the circuit board topside, the side not adjacent to the sensor, used in the connection assembly and embodied in the invention;

FIG. 3 illustrates the bottom side of the thin circuit board shown in FIG. 3;

FIG. 4. is an embodiment of the connection assembly;

FIG. 5 further illustrates the embodiment of FIG. 4 by means of a topside view with the integrated circuit sensor shown below the thin circuit board;

FIG. 6 further illustrates the embodiment of FIG. 4 by means of the cross-sectional view defined as A-B in FIG. 5;

FIG. 7 is an additional embodiment of the connection assembly using the cross-sectional view of FIG. 6;

FIG. 8 illustrates a representative sensor with the sensor area occupying one corner of the integrated circuit sensor surface; and

FIG. 9. is an embodiment of the connection assembly including the integrated circuit sensor shown in FIG. 8.

The figures are merely schematic and have not been drawn to any consistent scale. The same reference numbers are used throughout to represent the same or similar elements.

### DETAILED DESCRIPTION OF EMBODIMENTS OF THE INVENTION

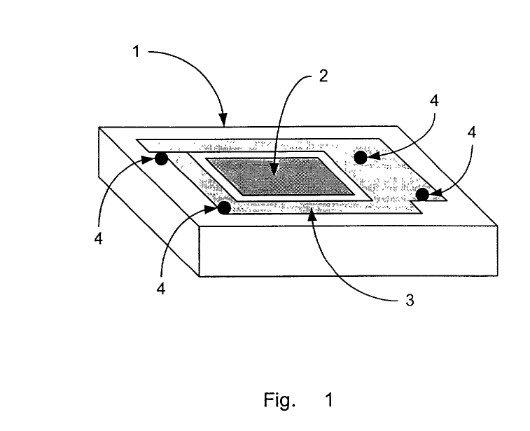

A typical integrated circuit sensor is illustrated in FIG. 1. The entire integrated circuit sensor (1), the sensor area containing the sensor elements (2), the ancillary electrical circuits (3), and the connection areas (4) are shown. The ancillary electrical circuits (3) perform functions necessary for the operation of the sensor. The electrical circuits contain transistors within the region (3). The sensor area (2) may also contain transistors. The connection areas (4) are illustrated as structures above the integrated circuit sensor surface (1), such as bumps, but the conduction areas (4) may also be openings to conductive films below the surface.

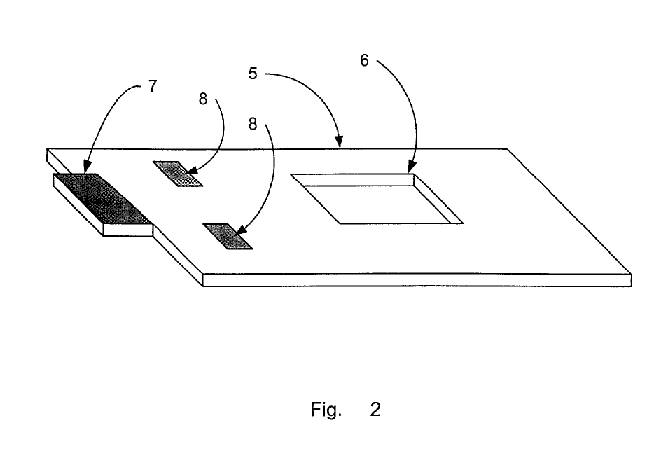

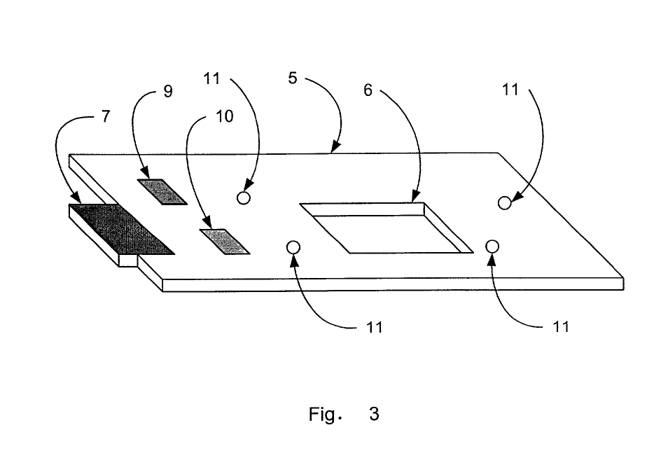

A circuit board is used to make electrical connection to the connection areas (4) and also protects the electrical circuits (3) from environmental damage. The circuit board is a structure composed of an insulating film and conducting wires within it or on its surface. FIG. 2 shows such a thin circuit board (5). The illustration in FIG. 2 is the topside view of the circuit board. FIG. 3 shows the opposite side of the circuit board when flipped parallel to the bottom of the figure.

The thin circuit board contains an opening (6) approximately the size of the sensor area (4), though it may be sized differently. The circuit board also contains connections areas (11) which are in the locations that match those of the integrated circuit connection areas (4). The circuit board also contains connections from the connection areas (11) to other connection points (7), (8), and (9). These other connection points allow the integrated circuit sensor (1) to be connected to an electrical system by means of a side connector (7) or to top connection points (8) or to bottom connection points (9) or to other components attached to the circuit board (10).

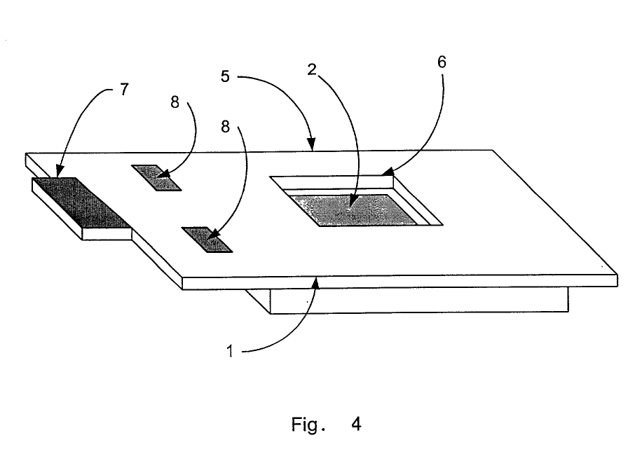

Together, the circuit board (5) and integrated circuit sensor (1) form the connection assembly which is the embodiment of the invention shown in FIG. 4. The circuit board (5) is attached to the integrated circuit sensor (1) by aligning the connection areas on the circuit board (11) to the connection areas (4) on the integrated circuit sensor (1). Once aligned, the connection areas (4), (11) are electrically connected between the circuit board (5) and integrated circuit sensor (1) by means of suitable operations and materials. These materials and the corresponding operations include conductive organic materials, an-isotropic conductive films, solder pastes, and/or the application of heat and/or pressure These materials and the corresponding operations cause the two connection areas (4), (11) to become electrically connected. These methods of connection also provide mechanical connection between the circuit board (5) and integrated circuit sensor (1). FIG. 4. illustrates the feature of the connection assembly that only the sensor area (2) and the circuit board, electrical connections (7), (8) are accessible from the topside of the sensor assembly.

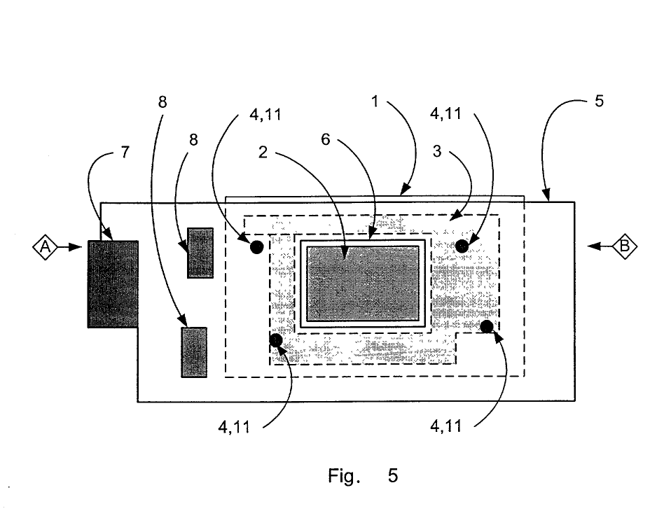

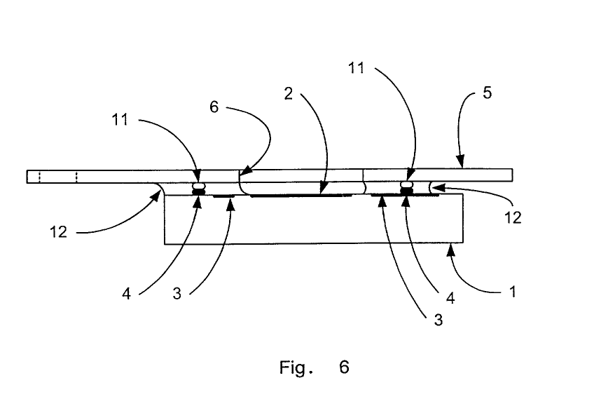

FIG. 5 depicts a transparent view of the sensor assembly as viewed from directly above the connection assembly shown in FIG. 4. The circuit board (5) covers the electrical circuit areas (3). The opening in circuit board (6) exposes the sensor area (2). Because of the protection provided by the circuit board (5) and the proximity of the opening (6) to the electrical circuit area, a more rugged integrated circuit sensor may be constructed by moving transistors from the sensor area (2) to the electrical circuit area (3) whenever possible. The connection areas (4), (11) align so that both are illustrated as one in this view. FIG. 6 further illustrates the features of the connection assembly by means of a cross section through the connection assembly defined by a vertical plane containing points A and B in FIG. 5.

The alignment of the connection areas (4) and (11) is again shown. The differences between the materials in connection area (4) and connection area (11) is illustrated as black and white. If the connection is made via some forms of solder connection, the connection materials blend together more than is currently depicted. The covering of the electrical circuits (3) by the circuit board (5) is shown as is the opening (6) above the sensor area (2). Also shown is an optional insulating sealant material (12) which provides additional protection for the connection areas (4), (11) and the electrical circuits (3) and increases the mechanical strength between the circuit board and the integrated circuit sensor. This sealant material may be applied after the circuit board is connected to the sensor, as in the case of an under-fill material, or as part of the electrical connection process itself, as in the case of anisotropic conductive film.

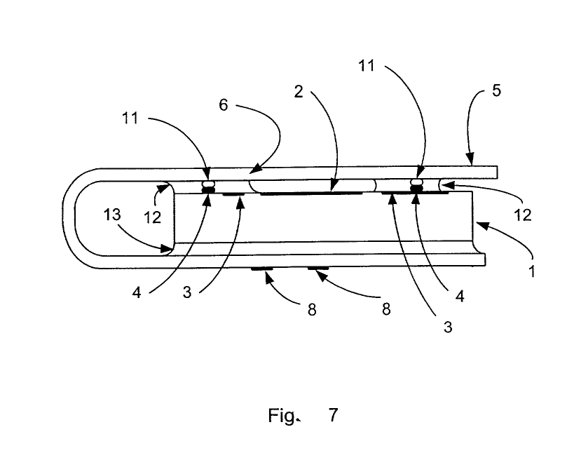

FIG. 7 shows another embodiment of the invention using the same physical cross section plane identified in FIG. 6. The thin circuit board (5) is physically attached to the side of the integrated circuit sensor opposite the sensor area (2), with adhesive material (13). Because of the bending of the circuit board, connection points (8) are advantageously located on the backside of the integrated circuit sensor.

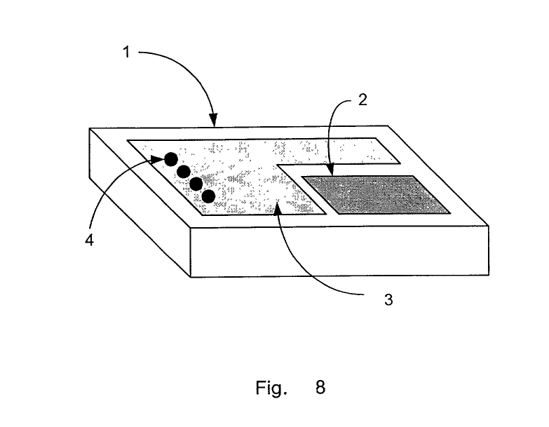

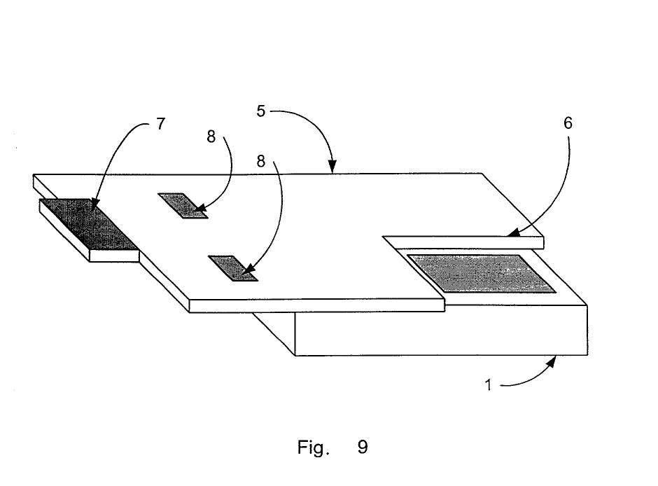

FIG. 8 shows an alternate integrated circuit sensor with sensor area (2) adjacent to the edge of the integrated circuit sensor (1). FIG. 9 shows another embodiment of the invention which also uses a circuit board that only exposes the integrated circuit surface at the sensor area (2). The circuit board opening (6) is a notch in the corner of the circuit board rather than a hole as in FIG. 4.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best use the invention and various embodiments with various modifications as are suited to the particular use contemplated. It is intended that the scope of the invention be defined by the claims appended hereto and their equivalents.

What is claimed is:

1. A connection assembly comprising:
an integrated circuit sensor;
a circuit board with both connection points that substantially match the locations of the integrated circuit sensor and openings in the circuit board primarily over the sensor area; and
connections between the matching connection points of the circuit board and the integrated circuit sensor.

2. The connection assembly in claim 1, wherein an insulating material is placed between circuit board and the integrated circuit sensor.

3. The connection assembly in claim 1, wherein the circuit board is also Mechanically attached to the backside of the integrated circuit sensor.

4. The connection assembly in claim 2, wherein the circuit board is also mechanically attached to the backside of the integrated circuit sensor.

5. A device comprising:
an integrated circuit;
a circuit board having a plurality of connection points that substantially match the locations of the integrated circuit and openings in the circuit board primarily over a predetermined area;
connections between the matching connection points of the circuit board and the integrated circuit;
an insulating material is placed between circuit board and the integrated circuit; and
the circuit board is mechanically attached to the backside of the integrated circuit.

6. The device in claim 5, wherein the integrated circuit includes a sensor and the predetermined area comprises an area of said sensor.

7. A method for making the electrical and physical connection between an integrated circuit sensor and an electronic system.
